(19) United States
(12) Patent Application Publication
(10) Pub. No.: US 2021/0260899 A1
(43) Pub. Date: Aug. 26, 2021

(54) COOLING DEVICE AND LIQUID DISCHARGE APPARATUS

(71) Applicants: Katsuhiro Tobita, Ibaraki (JP); Yasuhiko Kachi, Kanagawa (JP); Yuuya Nakazawa, Kanagawa (JP)

(72) Inventors: Katsuhiro Tobita, Ibaraki (JP); Yasuhiko Kachi, Kanagawa (JP); Yuuya Nakazawa, Kanagawa (JP)

(73) Assignee: Ricoh Company, Lt.d, Tokyo (JP)

(21) Appl. No.: 17/182,138

(22) Filed: Feb. 22, 2021

(30) Foreign Application Priority Data
Feb. 25, 2020 (JP) 2020-029741
Sep. 29, 2020 (JP) 2020-164189

(51) Int. Cl. B41J 29/377; H01L 23/473; H01L 23/40; F28F 27/02

(52) U.S. Cl. CPC B41J 29/377; H01L 23/473; H01L 23/4006; H01L 25/115; F28F 2275/00; H01L 2023/4087; F28F 27/02

(57) ABSTRACT

A cooling device includes a metal member, a cooling member, and a sheet-shaped thermal conductive member. The metal member thermally couples with an element that generates heat. The cooling member includes a channel for refrigerant to flow. The thermal conductive member includes an adhesive surface adhered to the metal member and a non-adhesive surface pressed against and thermally coupled in contact with the cooling member. The thermal conductive member and the cooling member are separable.

### CROSS-REFERENCE TO RELATED APPLICATIONS

This patent application is based on and claims priority pursuant to 35 U.S.C. § 119(a) to Japanese Patent Application Nos. 2020-029741, filed on Feb. 25, 2020, and 2020-164189, filed on Sep. 29, 2020, in the Japan Patent Office, the entire disclosure of each of which is incorporated by reference herein.

### BACKGROUND

### Technical Field

Aspects of the present disclosure relate to a cooling device and a liquid discharge apparatus.

### Related Art

In a liquid discharge apparatus, there are provided components that generate heat such as a pressure generator a driving IC (Integrated Circuit) as driver IC and a head drive board. The pressure generator includes, for example, a piezoelectric element consisting a head. The driving IC includes, for example, a switching circuit. The head drive board includes, for example, a power amplifier that generates a drive waveform and drives the piezoelectric element.

### SUMMARY

In an aspect of the present disclosure, there is provided a cooling device that includes a metal member, a cooling member, and a sheet-shaped thermal conductive member. The metal member thermally couples with an element that generates heat. The cooling member includes a channel for refrigerant to flow. The thermal conductive member includes an adhesive surface adhered to the metal member and a non-adhesive surface pressed against and thermally coupled in contact with the cooling member. The thermal conductive member and the cooling member are separable.

In another aspect of the present disclosure, there is provided a liquid discharge apparatus that includes the cooling device.

### BRIEF DESCRIPTION OF THE DRAWINGS

The aforementioned and other aspects, features, and advantages of the present disclosure would be better understood by reference to the following detailed description when considered in connection with the accompanying drawings, wherein:

FIG. 1 is a schematic view of a printer as a liquid discharge apparatus according to a first embodiment of the present disclosure;

FIG. 2 is a plan view of a head unit constituting a discharge unit of the printer, viewed from a nozzle surface side of the head unit;

FIG. 3 is a cross-sectional view illustrating a liquid discharge head, taken along a short direction (a direction orthogonal to a nozzle array direction of the liquid discharge head);

FIG. 4 is a plan view of a refrigerant channel taken along a line A-A of FIG. 3;

FIG. 5 is a perspective view illustrating a configuration of ports of ink and refrigerant of the liquid discharge head of FIG. 3;

FIG. 6 is a block diagram illustrating a configuration of a drive control system of the liquid discharge head;

FIG. 7 is a block diagram illustrating a configuration of a head drive controller mounted on a drive board;

FIG. 8 is a perspective view of a cooling device according to the first embodiment of the present disclosure;

FIG. 9 is a plan view of the cooling device of FIG. 8;

FIG. 10 is a front view of the cooling device of FIG. 8;

FIG. 11 is a perspective view illustrating a configuration of the drive board;

FIG. 12 is a plan view illustrating a configuration of the drive board;

FIG. 13 is a schematic view illustrating a configuration of a cooling member that cools the drive board, and a refrigerant circulating system for the cooling member;

FIG. 14 is an enlarged plan view illustrating a configuration of a mounting portion of the drive board and a water cooling jacket, for describing attachment and detachment of the drive board with respect to the water cooling jacket;

FIG. 15 is a schematic view illustrating a configuration including the inside of the drive board, for describing thermal conduction from a drive element to the water cooling jacket;

FIG. 16 is a schematic side view illustrating a configuration of a fixing structure of the water cooling jacket and the drive board;

FIG. 17 is an exploded perspective view illustrating a configuration of the fixing structure of the water-cooling jacket and the driving board;

FIG. 18 is a perspective view of a drive board according to a second embodiment of the present disclosure;

FIG. 19 is a plan view of the driving board of FIG. 18; and

FIG. 20 is an exploded perspective view illustrating a configuration of a fixing structure of a water cooling jacket and the drive board according to the second embodiment of the present disclosure.

The accompanying drawings are intended to depict embodiments of the present disclosure and should not be interpreted to limit the scope thereof. The accompanying drawings are not to be considered as drawn to scale unless explicitly noted.

### DETAILED DESCRIPTION

In describing embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner and achieve similar results.

Although the embodiments are described with technical limitations with reference to the attached drawings, such description is not intended to limit the scope of the disclosure and all of the components or elements described in the embodiments of this disclosure are not necessarily indispensable.

Referring now to the drawings, embodiments of the present disclosure are described below. In the drawings for explaining the following embodiments, the same reference codes are allocated to elements (members or components) having the same function or shape and redundant descriptions thereof are omitted below.

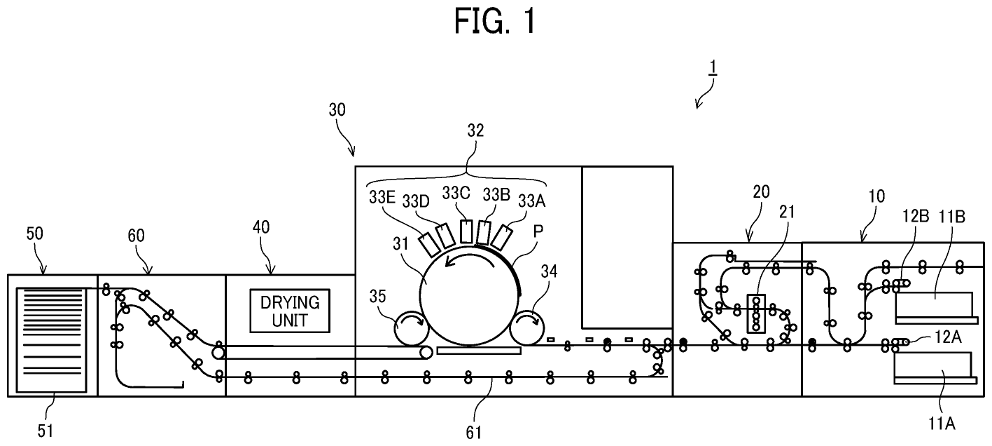

A printer as a liquid discharge apparatus according to a first embodiment of the present disclosure is described with reference to FIG. 1. FIG. 1 is a schematic view of the printer.

A printer 1 according to the present embodiment includes a loading unit 10 to load a sheet P into the printer 1, a pretreatment unit 20, a printing unit 30, a drying unit 40, an unloading unit 50, and a reverse mechanism 60. In the printer 1, the pretreatment unit 20 applies, as required, pretreatment liquid onto the sheet P fed (supplied) from the loading unit 10, the printing unit 30 applies liquid to the sheet P to perform printing, the drying unit 40 dries the liquid adhering to the sheet P, and the sheet P is ejected to the unloading unit 50.

The loading unit 10 includes loading trays 11 (a lower loading tray 11A and an upper loading tray 11B) to accommodate a plurality of sheets P and feeding devices 12 (a feeding device 12A and a feeding device 12B) to separate and feed the sheets P one by one from the loading trays 11, and supplies the sheets P to the pretreatment unit 20.

The pretreatment unit 20 includes, e.g., a coater 21 as a treatment-liquid applying device that coats an image formation surface of a sheet P with a treatment liquid having an effect of aggregating colorant of ink to prevent bleed-through.

The printing unit 30 includes a drum 31 and a liquid discharge unit 32. The drum 31 is a bearer (as a rotator) that bears the sheet P on the circumferential surface of the drum 31 and rotates. The liquid discharge unit 32 discharges a liquid toward the sheet P borne on the drum 31.

The printing unit 30 includes transfer cylinders 34 and 35. The transfer cylinder 34 receives the sheet P from the pretreatment unit 20 and forwards the sheet P to the drum 31. The transfer cylinder 35 receives the sheet P conveyed by the drum 31 and forwards the sheet P to the drying unit 40.

The transfer cylinder 34 includes a gripper (a sheet gripper) to grip the leading end of the sheet P conveyed from the pretreatment unit 20 to the printing unit 30. The sheet P thus gripped is conveyed as the transfer cylinder 34 rotates. The transfer cylinder 34 forwards the sheet P to the drum 31 at a position opposite the drum 31.

Similarly, the drum 31 includes a gripper (a sheet gripper) on a surface of the drum 31, and the leading end of the sheet P is gripped by the gripper (the sheet gripper) of the drum 31. The drum 31 has a plurality of suction holes dispersedly on the surface thereof, and a suction device generates suction airflows directed inward from suction holes of the drum 31.

On the drum 31, the sheet gripper grips the leading end of the sheet P forwarded from the transfer cylinder 34, and the sheet P is attracted to and borne on the drum 31 by the suction airflows by the suction device. As the drum 31 rotates, the sheet P is conveyed.

The liquid discharge unit 32 includes discharge units 33 (discharge units 33A to 33D) as liquid dischargers to discharge liquids. For example, the discharge unit 33A discharges a liquid of cyan (C), the discharge unit 33B discharges a liquid of magenta (M), the discharge unit 33C discharges a liquid of yellow (Y), and the discharge unit 33D discharges a liquid of black (K). In addition, a discharge unit to discharge a special liquid, that is, a liquid of spot color such as white, gold, or silver, can be used.

The discharge operation of each of the discharge units 33 of the liquid discharge unit 32 is controlled by a drive signal corresponding to print data. When the sheet P borne on the drum 31 passes through an area opposite the liquid discharge unit 32, the discharge units 33 discharge the respective color liquids to form or print an image according to the print data.

The drying unit 40 dries the liquid applied onto the sheet P by the printing unit 30. Thus, a liquid component such as moisture in the liquid evaporates, and the colorant contained in the liquid is fixed on the sheet P. Additionally, curling of the sheet P is restrained.

The reverse mechanism 60 reverses, in switchback manner, the sheet P that has passed through the drying unit 40 in double-sided printing. The reversed sheet P is fed back to the upstream side of the transfer cylinder 34 through a conveyance passage 61 of the printing unit 30.

The unloading unit 50 includes an unloading tray 51 on which a plurality of sheets P is stacked. The plurality of sheets P conveyed from the reverse mechanism 60 is sequentially stacked and held on the unloading tray 51.

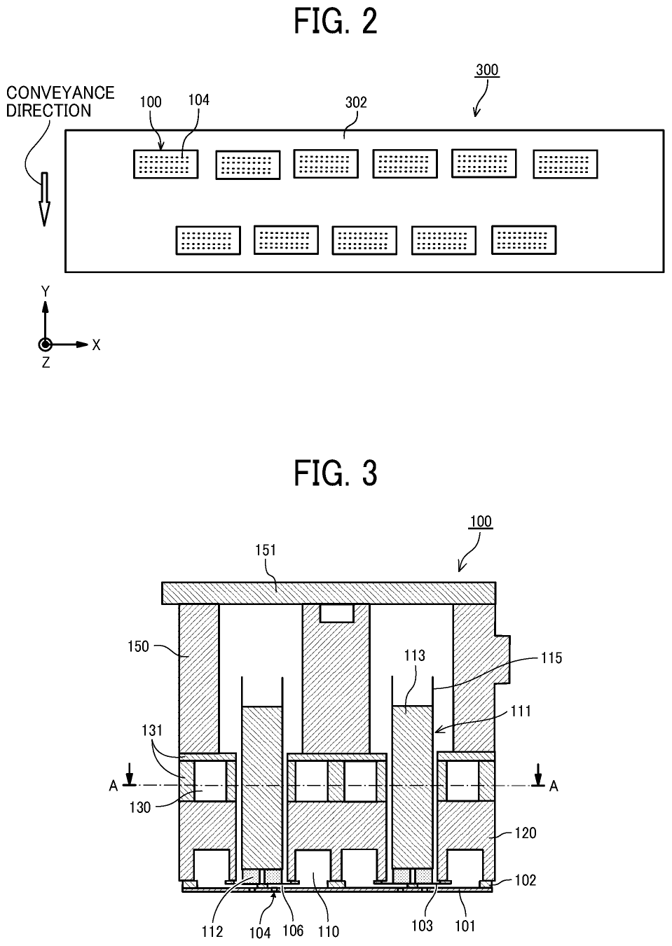

Next, an example of the head unit constituting the discharge unit will be described with reference to FIG. 2. FIG. 2 is a plan view of the head unit viewed from a nozzle surface side of the head unit.

In the head unit 300, a plurality of heads 100 that discharge liquid are arranged in a staggered manner in a head array direction on a head base 302.

Each of the heads 100 includes a plurality of nozzle arrays in which a plurality of nozzles 104, from which the liquid is discharged, is arrayed. Here, a number of nozzle arrays is not limited to four as illustrated in FIG. 2 and may be any number.

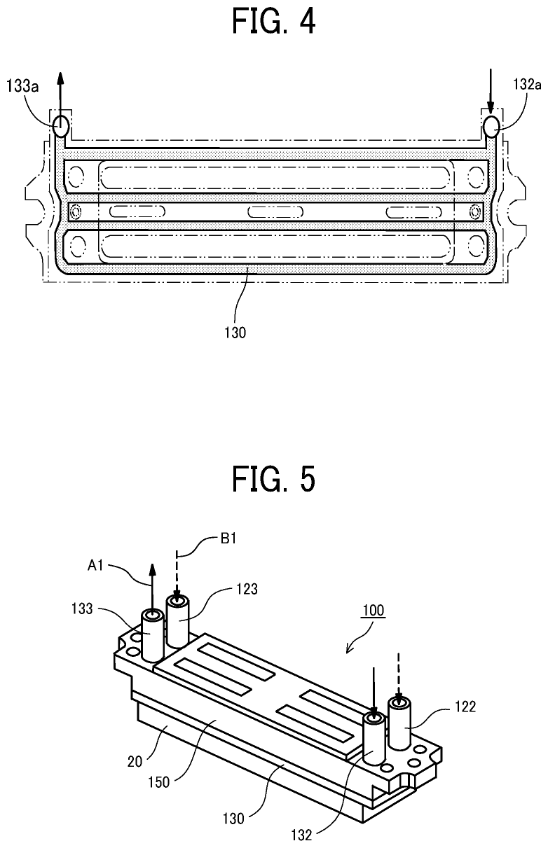

Next, an example of the head 100 is described with reference to FIGS. 3 to 5. FIG. 3 is a cross-sectional view of the head 100 taken along the short direction (a direction orthogonal to a nozzle array direction of the head 100). FIG. 4 is a plan view of a refrigerant channel 130 in A-A line of FIG. 3. FIG. 5 is a perspective view illustrating ports of ink and refrigerant of the head 100.

The head 100 includes a nozzle plate 101, a channel substrate 102, and a diaphragm 103 that are stacked one on another. The nozzles 104 are formed in the nozzle plate 101. The channel substrate 102 forms a channel such as a pressure chamber 106 communicated with the nozzle 104. The diaphragm 103 forms a wall surface of the pressure chamber 106. The head 100 includes a piezoelectric actuator 111 as a pressure generator and a frame member 120 that is a housing portion also serving as a common channel member.

The piezoelectric actuator 111 includes a plurality of columnar piezoelectric elements 112 fixed on the base 113 and bonded on the diaphragm 103. A wiring member 115 such as a flexible wiring board is connected to the piezoelectric element 112.

The frame member 120 also serving as a common channel member forms a common supply channel 110 that supplies liquid (ink) discharged into the pressure chamber 106.

A refrigerant channel member 131 that forms a refrigerant channel 130 in the head 100 to flow the refrigerant is bonded on the frame member 120. The refrigerant channel member 131 includes a refrigerant supply opening 132a to supply refrigerant to the refrigerant channel 130 and a refrigerant collection opening 133a to collect the refrigerant externally.

In this manner, the common supply channel 110 and the refrigerant channel 130 serving as ink channels are thermally coupled within the head 100. Further, the frame member 120 also serving as the housing portion of the head 100 forms a wall surface of the refrigerant channel 130 and is thermally coupled to the refrigerant channel 130 naturally.

A case member 150 and a lid member 151 are stacked one on another on the refrigerant channel member 131.

As illustrated in FIG. 5, the case member 150 includes an ink supply port 122 an ink supply port 123, a refrigerant supply port 132, and a refrigerant collection port 133. The ink supply port 122 and ink supply port 123 supply ink to the common supply channel 110 in a direction indicated by arrow B1 in FIG. 5. The refrigerant supply port 132 is connected to the refrigerant supply opening 132a of the refrigerant channel 130. The refrigerant collection port 133 is connected to the refrigerant collection opening 133a.

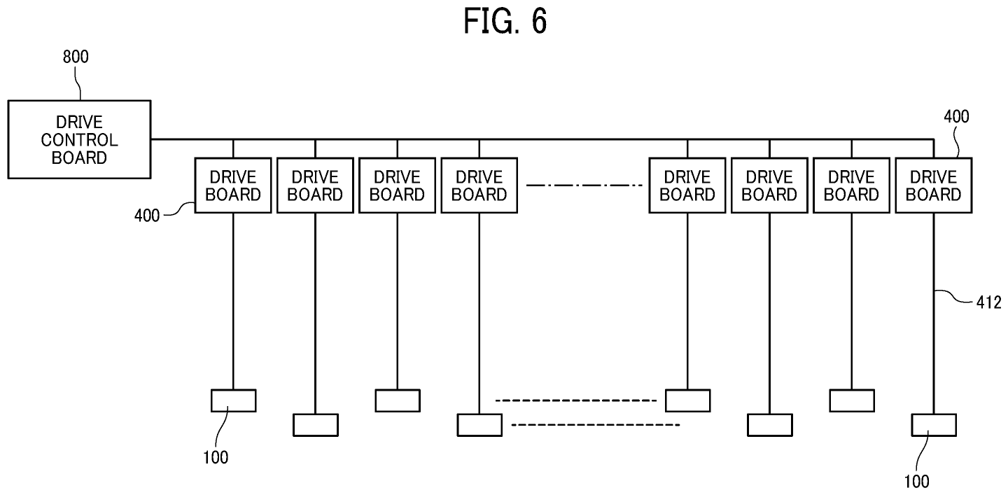

Next, a drive control system of the head according to an embodiment of the present disclosure is described with reference to the block diagram of FIG. 6.

Drive boards 400 generate drive waveforms and communicate analog signals and digital signals to the heads 100 via cables 412. A drive control board 800 transmits image data and so forth to each of the drive boards 400.

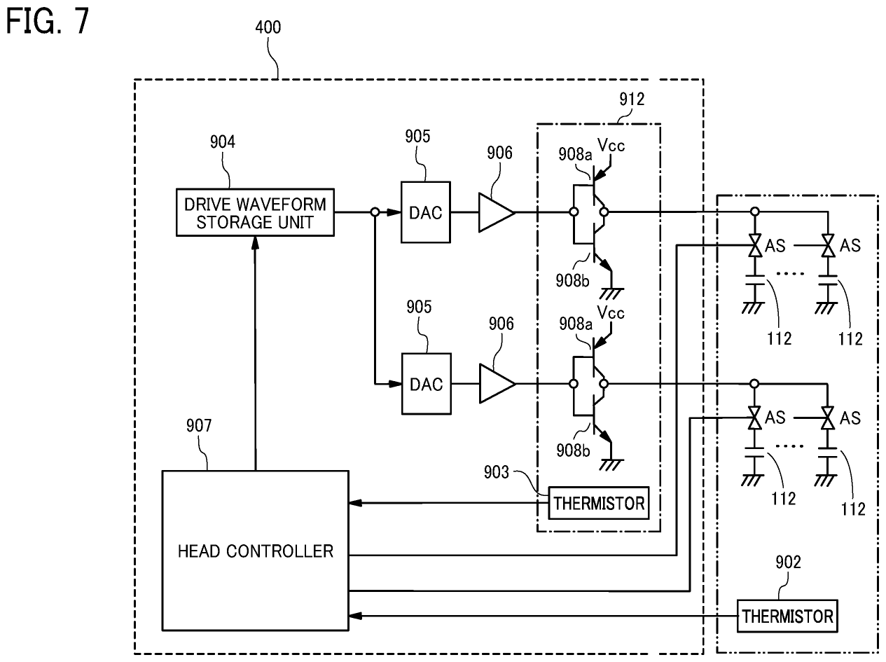

Next, a head drive controller mounted on the drive board 400 is described with reference to the block diagram of FIG. 7.

An analog switch AS is connected to each piezoelectric element 112 of the head 100. The analog switch AS is configured of a driving integrated circuit (IC) as a driver IC mounted on a wiring member 115 of the head 100.

The drive board 400 has a drive waveform storage unit 904 that stores drive waveform data to be sent to the piezoelectric element 112. Multiple drive waveform data are stored for different temperatures. The drive waveform data output from the drive waveform storage unit 904 is converted to an analog drive waveform by a digital-to-analog (D/A) converter 905. The drive waveform is voltage-amplified by a voltage amplifier 906, is current-amplified by a current amplifier 912, and supplied to the input side of the analog switch AS.

The current amplifier 912 is a push-pull circuit including a plurality of pairs of a transistor 908a and a transistor 908b, and outputs the current-amplified drive waveform to the analog switches AS of all piezoelectric elements 112 connected via a pair of transistors 908a and 908b.

The analog switch AS is used to select a required drive pulse waveform from the drive waveform. The analog switch AS is turned on and off by print data from a head controller 907. The print data are dot data corresponding to the discharge amount information indicating the droplet amount of liquid discharged from each nozzle 104, and include a data set of the total number of nozzles constituting the nozzle array.

A thermistor 902 is mounted inside the head 100 and detects the internal temperature of the head 100. The head controller 907 switches the drive waveform data output from the drive waveform storage unit 904 according to the temperature detected from the thermistor 902 so that the discharge amount of ink is constant even if the viscosity of ink changes due to the temperature change. The thermistor 903 is disposed in the current amplifier 912 and detects the overheat abnormality of the transistors 908.

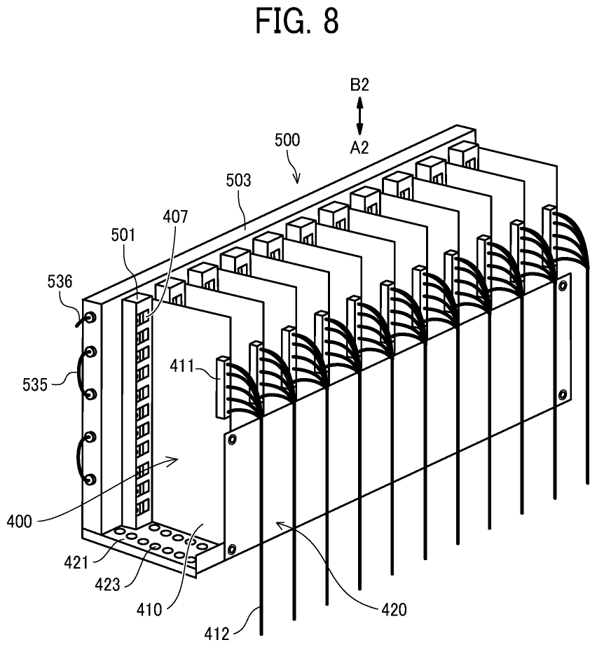

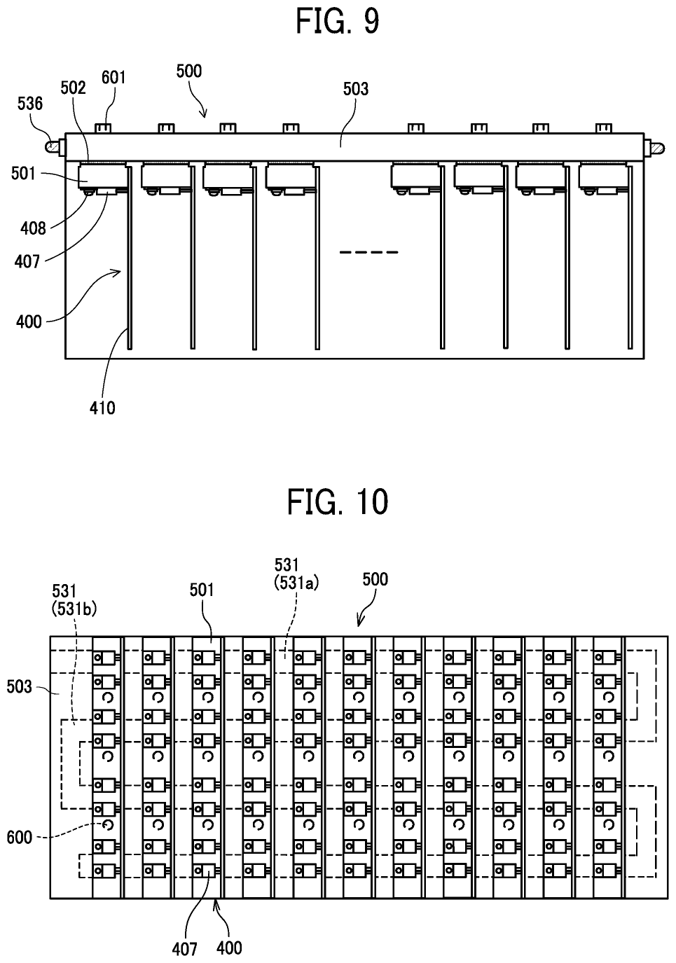

With reference to FIGS. 8 to 10, a description is given of a cooling device according to the first embodiment of the present disclosure. FIG. 8 is a perspective view of the cooling devise according to the first embodiment of the present disclosure. FIG. 9 is a plan view of the cooling devise of FIG. 8. FIG. 10 is a front view of the cooling devise of FIG. 8.

A cooling device 500 according to the first embodiment is a device that cools the drive boards 400 in the first embodiment. The cooling device 500 includes metal members 501 as heat radiators integrated with the drive boards 400, thermal conductive sheets 502 as sheet-shaped thermal conductive members, and a water cooling jacket 503 serving as a cooling member.

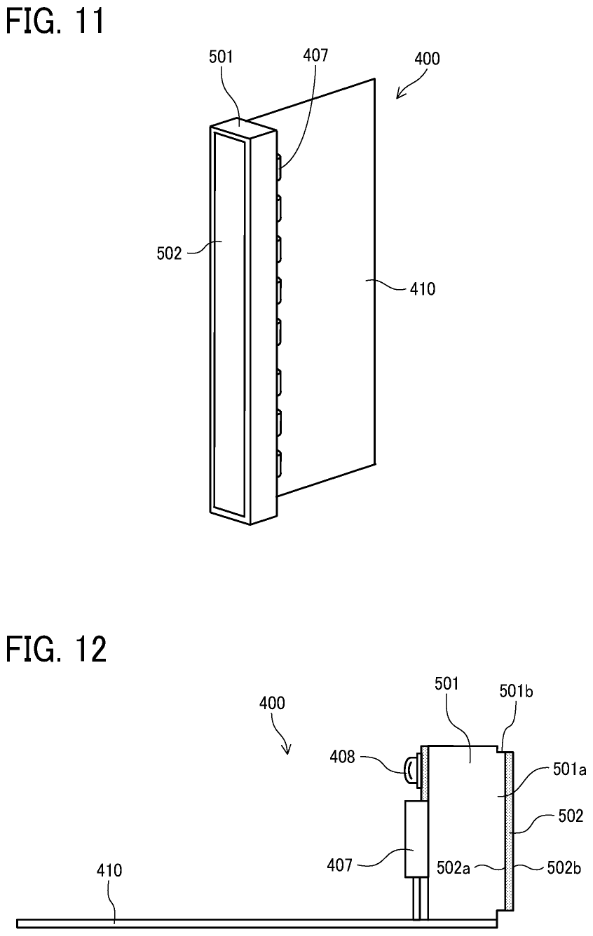

Here, the drive board 400 is described with reference to FIGS. 11 and 12. FIG. 11 is a perspective view of the drive board 400. FIG. 12 is a plan view of the drive board 400.

The drive board 400 is mounted on a plurality of drive elements 407 such as transistors, which are elements that generate heat on a printed wiring board (PWB) 410.

The plurality of drive elements 407 are fixed to the metal member 501 constituting the cooling device 500 by screws 408, and each of the drive elements 407 and the metal member 501 contact and are thermally coupled with each other. The metal member 501 is molded of, for example, an aluminum material (such as the A6063).

The thermal conductive sheet 502 constituting the cooling device 500 is adhered on the surface of the metal member 501 opposite to the drive elements 407.

The thermal conductive sheet 502 has an adhesive surface 502a and a non-adhesive surface 502b, and the adhesive surface 502a is constantly adhered to the metal member 501.

The thermal conductive sheet 502 is, e.g., a thermally conductive silicone, and has flexibility. Therefore, the contact thermal resistance can be lowered by applying pressure to the thermal conductive sheet 502. Since the thickness of the thermal conductive sheet 502 affects the thermal resistance, the thickness of the thermal conductive sheet 502 is preferably thin, for example, about 0.5 to 1.0 mm. The width of the thermal conductive sheet 502 is about 20 mm, and the length of the thermal conductive sheet 502 is 150 to 300 mm although may vary depending on the mounted drive elements 407.

The heat generated by the drive elements 407 is transmitted to the metal member 501 and can further be transmitted to the thermal conductive sheet 502.

The thermal conductive sheet 502 is constantly adhered to the metal member 501 and is integrated with the drive board 400 to form a maintenance component.

The thermal conductive sheet 502 is generally referred to as a thermal interface material. If the surfaces of the metal member 501 and the water cooling jacket 503 are warped or uneven when the metal member 501 is in contact with the water cooling jacket 503 serving as the cooling member, the contact thermal resistance increases and heat is not efficiently conducted. Therefore, the thermal conductive efficiency is increased by thermal coupling between the metal member 501 of the drive board 400 and the cooling member (the water cooling jacket 503) across the thermal conductive sheet 502.

If the drive element 407 is a surface-mounted component, the drive element 407 may be soldered directly to the printed wiring board 410. Therefore, the thermal conductive sheet 502 may be sandwiched between the printed wiring board 410 as a metal member (heat radiator) and the cooling member.

Referring back to FIGS. 8 to 10, the water cooling jacket 503 has a channel 531 for cooling refrigerant (refrigerant liquid).

The channels 531 include a plurality of horizontal channels 531a and a plurality of vertical channels 531b. The plurality of horizontal channels 531a are disposed along the array direction of the drive boards 400 that is the longitudinal direction of the water cooling jacket 503. The plurality of vertical channels 531b alternately connect ends of horizontal channels 531a adjacent to each other in the short direction of the water cooling jacket 503.

The plurality of horizontal channels 531a are channel portions that are arranged at intervals, and are arranged at substantially equal intervals in the vertical direction. As illustrated in FIG. 8, the horizontal channel 531a includes a vent portion 535. The vent portion 535 is formed of a tube or a molded member. A discharge tube 536 is connected to an end of the horizontal channel 531a as a terminal of the channel 531.

The metal member 501 attached to the drive board 400 is arranged in a direction orthogonal to the plurality of channels 531a of the water cooling jacket 503. That is, the plurality of horizontal channels 531a and the metal members 501 of the plurality of drive boards 400 are arranged in a lattice form. The drive element 407 is disposed opposite or close to the horizontal channel 531a (FIG. 10).

Accordingly, the metal member 501 has a long shape. However, since the plurality of horizontal channels 531a are allocated to a plurality of positions in the vertical direction of the metal member 501, the entire of the long metal member 501 can be cooled almost uniformly. Furthermore, the plurality of drive elements 407 can be cooled almost uniformly (within a few degrees of temperature difference).

The water cooling jacket 503 and the metal member 501 of the drive board 400 are fixed at a plurality of fixing positions (mounting positions) 600 that do not overlap with the horizontal channels 531a (see FIG. 10). As a result, influences to the channel resistance can be eliminated.

Each drive board 400 can be mounted with a common mounting structure, and any fixing position 600 can be selected and fixed in the longitudinal direction of the water cooling jacket 503 (in other words, in the array direction of the drive boards 400). That is, the position at which the metal member 501 is fixed to the cooling member can be selected.

Accordingly, the mounting number of the drive boards 400 can be thinned out and the drive boards 400 may be mounted, for example, only on odd-numbered positions. Thus, the same water cooling jacket 503 can be used as a cooling device 500 to cool the number of drive boards 400 corresponding to a half resolution of the maximum resolution.

The connector 411 is mounted on the printed wiring board 410 of the drive board 400 and connected to the head 100 described above via the cable (harness) 412.

The plurality of drive boards 400 are stored in a box-shaped case 420, and a plurality of air intake holes 423 that take airflow into the case 420 are disposed on a bottom portion 421 of the case 420.

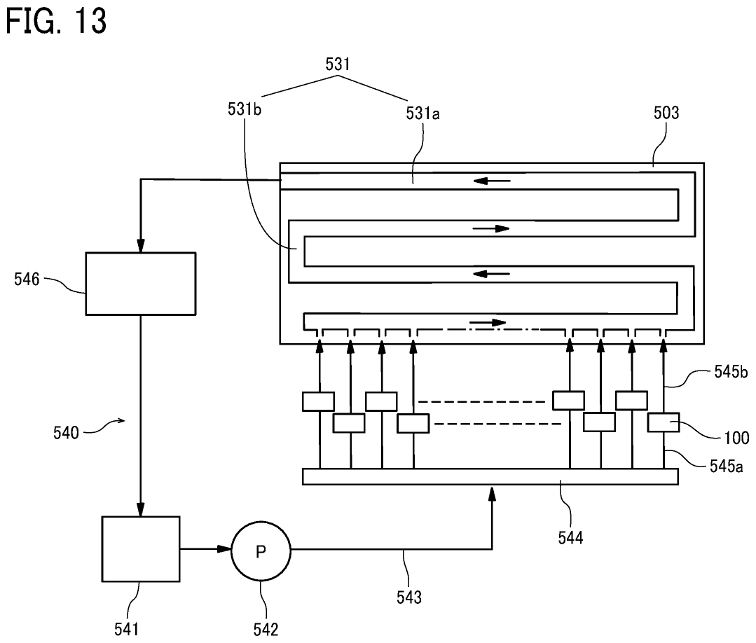

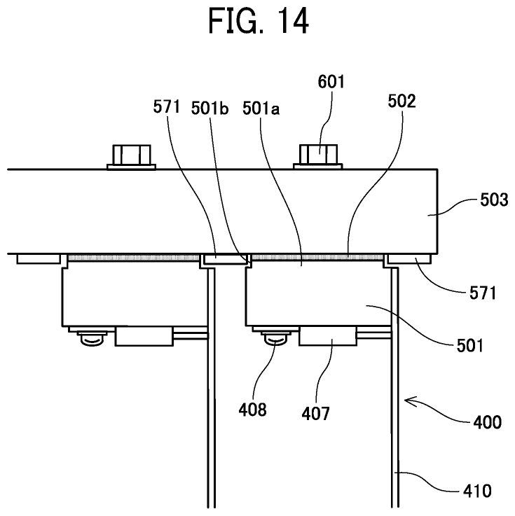

Next, the cooling member (the water cooling jacket 503) to cool the drive boards 400 and a refrigerant circulation system for the cooling member are also described with reference to FIG. 13. FIG. 13 is a schematic view of the cooling member and the refrigerant circulation system according to an embodiment of the present disclosure.

The heat generated from the drive element 407 of the drive board 400 is cooled by heat conduction from the metal member 501 to the water cooling jacket 503, which is a cooling member, via the thermal conductive sheet 502.

A refrigerant circulation system 540 for the water cooling jacket 503 supplies the refrigerant stored in a refrigerant tank 541 to a manifold 544 via a pump 542 via a tube 543.

The refrigerant in the manifold 544 is supplied to the refrigerant supply port 132 in each head 100 via a tube 545a, is collected from the refrigerant collection port 133 in a direction indicated by arrow A1 in FIG. 5 via the refrigerant channel 130, and flows to the horizontal channel 531a of the cooling jacket 503 via the tube 545b.

As a result, the temperature in the head 100 can be approximated to the temperature of the refrigerant, and the liquid temperature (e.g., ink temperature) inside the head 100 can be kept in a predetermined range, and the discharge characteristics of ink can be stabilized.

The refrigerant flowing into the water cooling jacket 503 flows through the plurality of horizontal channels 531a and the plurality of vertical channels 531b. In the present embodiment, the number of horizontal channels 531a of the channel 531 is four. However, the number of horizontal channels 531a is determined from the total amount of heat generation of the plurality of drive boards 400, the cooling ability of a radiator 546, and the flow rate of the refrigerant.

As described above, the plurality of drive boards 400 are attached to the water cooling jacket 503. The refrigerant heated in the head 100 and the water cooling jacket 503 is delivered to and cooled in the radiator 546. The refrigerant cooled in the radiator 546 is returned to the refrigerant tank 541 and circulated.

The material of the water cooling jacket 503 may be made of a material with excellent thermal conductivity such as aluminum. In the present embodiment, the refrigerant flows from the lower part of the channel 531 and is discharged from an upper discharge part via each channel 531.

Next, the attachment and detachment of the drive board 400 with respect to the water cooling jacket 503 is described with reference to FIG. 14. FIG. 14 is an enlarged plan view illustrating a configuration of a mounting portion of the drive board 400 and the water cooling jacket 503.

Referring to FIGS. 8 to 10 described above, the drive board 400 is disposed in such a direction that the longitudinal direction of the metal member 501 thermally coupled to the plurality of driving elements 407 is vertical. The plurality of drive boards 400 are arranged along the longitudinal direction of the water cooling jacket 503 at substantially even intervals on the vertical surface of the water cooling jacket 503.

The non-adhesive surface 502b side of the thermal conductive sheet 502 adhering to the metal member 501 is in contact with and connected to the vertical surface of the water cooling jacket 503, and the metal member 501 and the water cooling jacket 503 are thermally coupled via the thermal conductive sheet 502.

When the drive board 400 is attached, the drive board 400 is slid and pushed in the direction indicated by arrow A2 of FIG. 8 along a guide member 571 of the water cooling jacket 503 illustrated in FIG. 14. A screw 601 is tightened at a fixing position 600 to fasten and fix the drive board 400 to the water cooling jacket 503.

Accordingly, the non-adhesive surface 502b of the thermal conductive sheet 502 is in contact with the water cooling jacket 503 in a pressed state and is thermally coupled with the water cooling jacket 503. Therefore, the non-adhesive surface 502b of the thermal conductive sheet 502 and the water cooling jacket 503 are in a separable state each other.

On the other hand, when the drive board 400 is removed, the screw 601 is loosened and the water cooling jacket 503 is separated from the non-adhesive surface 502b of the thermal conductive sheet 502. The drive board 400 is pulled out while the drive board 400 is slid in the direction indicated by arrow B2 of FIG. 8.

As illustrated in FIGS. 12 and 14, the metal member 501 is convex in cross-sectional shape, with a portion to which the thermal conductive sheet 502 is adhered as a convex portion 501a.

Accordingly, two notched portions 501b on the thermal conductive sheet 502 side of the metal member 501 are opposed to the guide member 571, thus facilitating an alignment operation when the drive board 400 is inserted.

In the present embodiment, the metal member 501 of the drive board 400 is disposed in a vertical direction. However, the metal member 501 may be arranged horizontally. In this case, the channels 531 in the water cooling jacket 503 are preferably arranged with vertical channels 531b at required intervals.

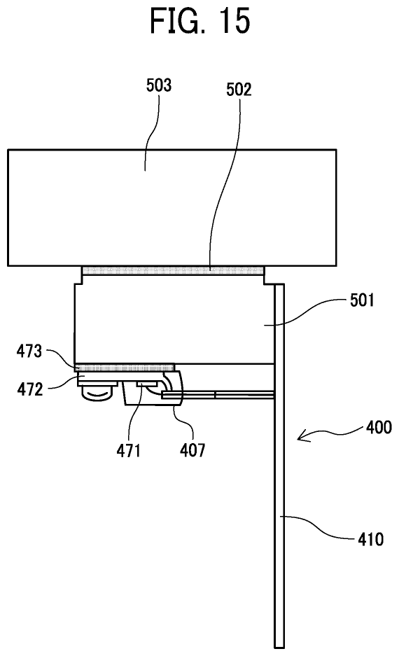

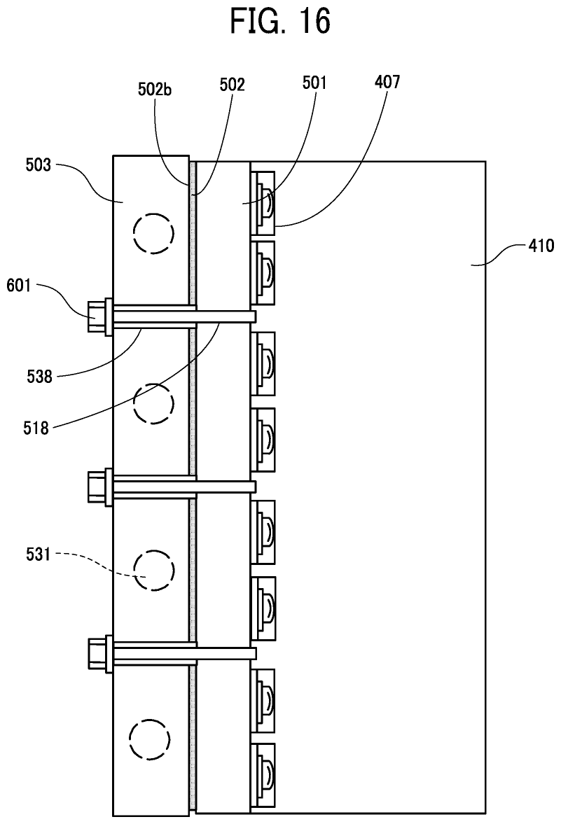

Next, the thermal conduction from the drive element 407 to the water cooling jacket 503 is also described with reference to FIG. 15. FIG. 15 is a schematic view illustrating a configuration of the drive element 407 including a cross-sectional view of the inside of the drive element 407 for describing the thermal conduction from the drive element 407 to the water cooling jacket 503.

Inside the drive element 407, a chip 471 as a heat source is provided. The chip 471 is mounted on a metal plate 472 (referred to as a heat spreader), and the chip 471 and the metal plate 472 are sealed with a mold package.

However, there is a type of package in which the metal plate 472 is exposed to the outside of the drive element 407, and such a configuration has an advantage that the thermal resistance from the chip 471 to the case is low.

An insulating thermal conductive sheet 473 for insulating and conducting heat is disposed between the metal plate 472 and the metal member 501. The thickness of the insulating thermal conductive sheet 473 is about 0.2 mm.

Accordingly, in the present embodiment, the heat generated by the chip 471 is transmitted to the metal plate 472 and transmitted to the metal member 501 via the insulating thermal conductive sheet 473. The heat of the metal member 501 can be transmitted to the water cooling jacket 503 via the thermal conductive sheet 502.

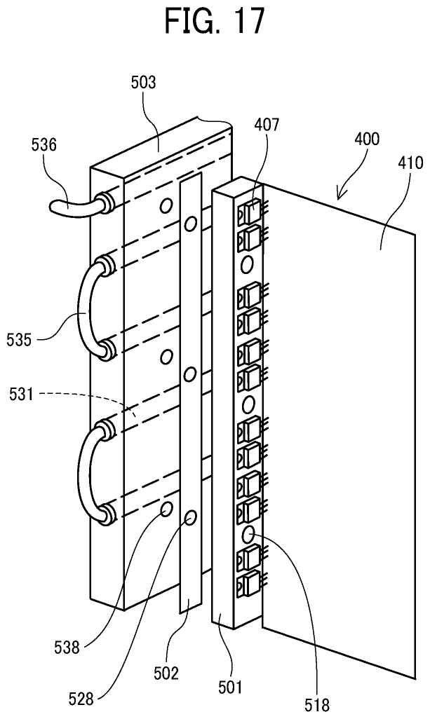

Next, a fixing structure of the water cooling jacket 503 and the drive board 400 is described with reference to FIGS. 16 and 17. FIG. 16 is a side view illustrating a configuration of the fixing structure, and FIG. 17 is an exploded perspective view illustrating a configuration of the fixing structure.

Since the fixing position 600 is set to a position of the water cooling jacket 503 away from the channel 531, a through-hole 538 is provided at a position corresponding to the fixing position 600 so that the screw 601 as a fastening member is inserted into the through-hole 538.

The metal member 501 of the drive board 400 is provided with a screw hole 518 at a position opposed to the through-hole 538.

The adhesive surface 502a of the thermal conductive sheet 502 having substantially the same size as the metal member 501 is adhered on the metal member 501 of the drive board 400.

The non-adhesive surface 502b of the thermal conductive sheet 502 in contact with the water cooling jacket 503 is, for example, a thermally conductive acrylic layer having non-adhesiveness. The thermal conductive sheet 502 is provided with the hole 528 to have a clearance for the screw 601 at a position opposed to the through-hole 538.

By inserting the screw 601 from the through-hole 538 of the water cooling jacket 503 and fastening to the screw hole 518 of metal member 501, the thermal conductive sheet 502 is pressed into contact with the water cooling jacket 503, and the water cooling jacket 503 and the metal member 501 are thermally coupled via the thermal conductive sheet 502.

Accordingly, the plurality of channels 531 (channels 531a) are allocated to a plurality of positions in the vertical direction of the long metal member 501 of each drive board 400, so that the drive elements 407 that are thermally coupled with the metal member 501 can be cooled almost uniformly to each other.

Thus, the adhesive surface 502a of the thermal conductive sheet 502 adheres to the metal member 501 that is thermally coupled to the drive elements 407, and the non-adhesive surface 502b of the thermal conductive sheet 502 is pressed against and contacted with the water cooling jacket 503.

At this time, the thermal conductive sheet 502 is constantly adhered to the metal member 501 and is integrated with the drive board 400. Accordingly, the metal member 501 on the drive board 400 can be fixed on the water cooling jacket 503 by the screws 601 without an alignment or paste operation of the thermal conductive sheet 502.

When the metal member 501 is fixed to the water cooling jacket 503, the thermal conductive sheet 502 is sandwiched between the metal member 501 and the water cooling jacket 503. Accordingly, pressure is applied to the thermal conductive sheet 502, and the contact resistance of the thermal conductive sheet 502 can be reduced. As a result, the heat of the metal member 501 can be efficiently transmitted to the water cooling jacket 503.

Thus, the alignment operation of the thermal conductive sheet 502 can be obviated, and the drive board 400 can be easily mounted on the water cooling jacket 503.

Since the non-adhesive surface 502b of the thermal conductive sheet 502 is in contact with the water cooling jacket 503, the water cooling jacket 503 and the non-adhesive surface 502b of the thermal conductive sheet 502 can be easily separated by removing the screws 601. Thus, the drive board 400 is easily removed without detaching the various water cooling tubes.

The adhesive on the adhesive surface 502a of the thermal conductive sheet 502 has a characteristic that the adhesive surface 502a can be peeled off from the water cooling jacket 503. Therefore, when the thermal conductive sheet 502 is damaged such as torn, only the thermal conductive sheet 502 adhered to the drive board 400 side needs to be replaced, so that the thermal conductive sheet 502 can be easily replaced.

Furthermore, the thermal conductive sheet 502 is not adhered to the water cooling jacket 503 but is adhered to the metal member 501 of the drive board 400. Accordingly, the size of the thermal conductive sheet 502 is equivalent to the size of the metal member 501, thus allowing cost reduction due to downsizing and facilitating adhesion of the thermal conductive sheet 502. Since the size of the thermal conductive sheet 502 is equivalent to the size of the metal member 501, the thermal conductive sheet 502 can be prevented from being damaged during transportation, and the thermal conductive sheet 502 can be superior in handleability as a maintenance part.

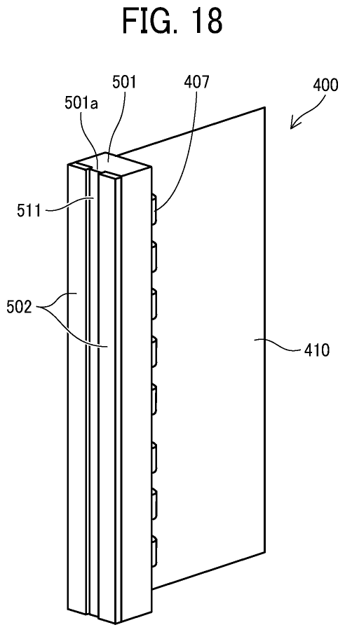

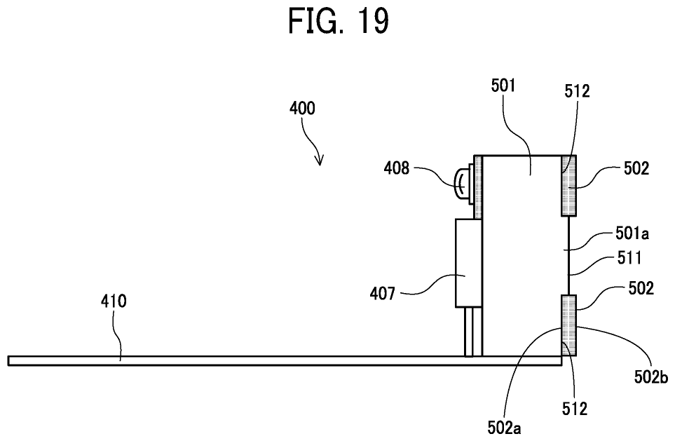

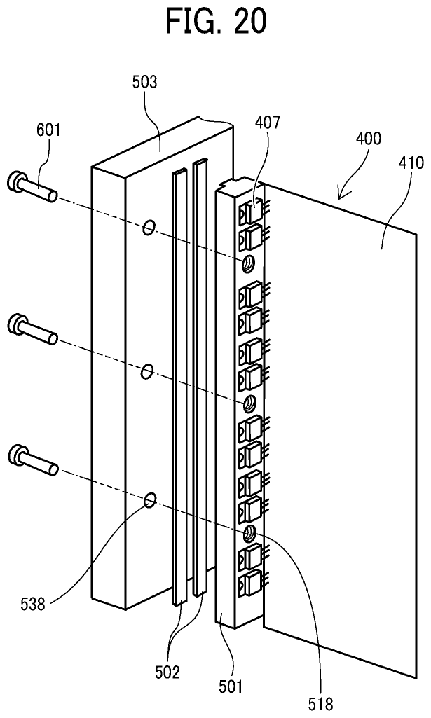

Next, a second embodiment of the present disclosure is described with reference to FIGS. 18 to 20. FIG. 18 is a perspective view illustrating a configuration of a drive board according to the second embodiment of the present disclosure. FIG. 19 is a plan view of the drive board of FIG. 18. FIG. 20 is an exploded perspective view illustrating a configuration of a fixing structure of a water cooling jacket and the drive board of FIG. 18.

Drive elements 407 are mounted on a printed wiring board 410 on a drive board 400 according to the present embodiment. The drive elements 407 are fixed on a metal member 501 such as aluminum by screws 408. Two thermal conductive sheets 502 are adhered along the longitudinal direction of the metal member 501 on the surface of the metal member 501 opposite to the surface on which the drive elements 407 are mounted.

The metal member 501 is provided with a convex portion 501a, and a first face 511 in a protruding form and two second faces 512 lower than the first face 511 are provided as a protruding shape in cross section that protrudes toward the opposite side of the surface on which the drive elements 407 are mounted. The thermal conductive sheets 502 of substantially the same size (including the same size) are adhered on the two second faces 512 along the longitudinal direction of the second faces 512.

Here, the difference between the first face 511 and the second face 512 of the metallic member 501, i.e., the height of the convex portion 501a is half of the thickness (nominal thickness dimension) of the thermal conductive sheet 502. Accordingly, when the metal member 501 and the water cooling jacket 503 are fixed by the fastening members (screws 601), the compression ratio of the thermal conductive sheet 502 is 50%.

However, the height of the convex portion 501a is not limited to the height at which the compression ratio of the thermal conductive sheet 502 is 50%. The height of the convex portion 501a is preferably set so that the compression ratio is 20% or more in order to reduce the contact thermal resistance of the thermal conductive sheet 502.

The water cooling jacket 503 is fixed to the first face 511 of the metal member 501. The water cooling jacket 503 is provided with through-holes 538 through which the screws 601 as fastening members are inserted. Screw holes 518 are provided on the first face 511 of the metal member 501 of the drive board 400 at positions opposite to the through-holes 538.

By inserting the screws 601 from the through-holes 538 of the water cooling jacket and tightening the screws 601 into the screw holes 518 of the metal member 501, the first face 511 protruding into the convex shape of the metal member 501 and the surface of the water cooling jacket 503 are fixed metal to metal.

At this time, the thermal conductive sheets 502 is pressed to contact the water cooling jacket 503, and the water cooling jacket 503 and the metal member 501 are thermally coupled via the thermal conductive sheets 502. In other words, the thermal conductive sheets 502 are pressed against and disposed on the second faces 512 of the metal member 501.

As described above, since the first face 511 protruding to form the convex shape of the metal member 501 and the surface of the water cooling jacket 503 are fixed metal to metal, the looseness of the screws 601 due to the plastic deformation of the thermal conductive sheets 502 can be restrained.

The first face 511 of the metal member 501 is fixed in contact with the surface of the water cooling jacket 503. Accordingly, the thickness of the thermal conductive sheet 502 after pressing is defined by the height of the convex portion 501a of the metal member 501, and the compression ratio of the thermal conductive sheet 502 can be kept constant.

When the thermal conductive sheet 502 is compressed and pressed, the contact pressure in the thickness direction increases and the contact thermal resistance decreases. In other words, the thermal resistance of the thermal conductive sheet 502 can be calculated by dividing the thickness by a product of the thermal conductivity and the area of the thermal conductive sheet 502. Accordingly, the thermal resistance of the thermal conductive sheet 502 can be reduced by setting the compression ratio of the thermal conductive sheet 502 to 50% and reducing the thickness dimension.

When the thermal conductive sheet 502 is pressed on the metal member 501 by hand, the thermal conductive sheet 502 is compressed and plastically deformed by the pressure. Accordingly, a gap is generated in the contact surface between the thermal conductive sheet 502 and the water cooling jacket 503. However, by compressing the thermal conductive sheet 502, the gap between the contact surface of the thermal conductive sheet 502 and the water cooling jacket 503 can be eliminated.

The cross sectional shape of the metal member 501 is not limited to a convex shape, and it is sufficient that there is at least one second face 512 that is lower than the first face 511. With such a configuration, a margin for determining the shape of the metal member 501 is increased.

Further, although the number of the thermal conductive sheets 502 is two in the present embodiment, one may be used depending on the cooling conditions.

As described above, the convex shape of the metal member 501 formed by the convex portion 501a maintains a constant compression of the thermal conductive sheet 502 and serves as a spacer to secure the metal member 501 and the water cooling jacket 503.

The convex shape of the metal member 501 can be manufactured by aluminum extrusion molding, so that the convex shape can be manufactured at low cost and the number of parts can be reduced.

In the above-described embodiments, the examples that the adhesive surface of the thermal conductive member is constantly adhered to the metal member and the non-adhesive surface is pressed against the cooling member to be thermally coupled are described. However, the reverse configuration can also be used. In other words, the adhesive surface of the thermal conductive member may be adhered to the cooling member, and the non-adhesive surface may be pressed against the metal member so as to be thermally coupled.

In such a configuration, since the thermal conductive member and the metal member are not adhered, the metal member can be easily removed from the cooling member, and the maintenance workability can be enhanced.

In the embodiments of the present disclosure, the liquid to be discharged is not limited to a particular liquid provided that the liquid has a viscosity or surface tension dischargeable from a head. However, preferably, the viscosity of the liquid is not greater than 30 millipascal-second (mPa·s) under ordinary temperature and ordinary pressure or by heating or cooling. More specifically, the liquid to be discharged is a solution, a suspension liquid, an emulsion, or the like containing a solvent such as water or an organic solvent, a colorant such as a dye or a pigment, a function-imparting material such as a polymerizable compound, a resin, or a surfactant, a biocompatible material such as deoxyribonucleic acid (DNA), amino acid, protein, or calcium, or an edible material such as a natural pigment, which can be used, for example, for an inkjet ink, a surface treatment liquid, a liquid for forming a constituent element of an electronic element or a light emitting element or an electronic circuit resist pattern, a three-dimensional modeling material liquid, or the like.

Examples of an energy source for generating energy to discharge liquid in a head include a piezoelectric actuator (a laminated piezoelectric element or a thin-film piezoelectric element), a thermal actuator that employs a thermoelectric conversion element, such as a thermal resistor, and an electrostatic actuator including a diaphragm and opposed electrodes.

Examples of the “liquid discharge apparatus” include, not only apparatuses capable of discharging liquid to materials to which liquid can adhere, but also apparatuses to discharge a liquid toward gas or into a liquid.

The “liquid discharge apparatus” may include at least one of devices for feeding, conveying, and ejecting a material to which liquid is adherable. The liquid discharge apparatus may further include at least one of a pre-processing device and a post-processing device.

The “liquid discharge apparatus” may be, for example, an image forming apparatus to form an image on a sheet by discharging ink, or a three-dimensional fabrication apparatus to discharge a fabrication liquid to a powder layer in which powder material is formed in layers to form a three-dimensional fabrication object.

The “liquid discharge apparatus” is not limited to an apparatus to discharge liquid to visualize meaningful images, such as letters or figures. For example, the liquid discharge apparatus may be an apparatus to form meaningless images, such as meaningless patterns, or fabricate three-dimensional images.

The above-described term “material to which liquid can adhere” denotes, for example, a material or a medium to which liquid can adhere at least temporarily, a material or a medium to which liquid can attach and firmly adhere, or a material or a medium to which liquid can adhere and into which the liquid permeates. Examples of the “material to which liquid can adhere” include recording media, such as paper sheet, recording paper, recording sheet of paper, film, and cloth, electronic component, such as electronic substrate and piezoelectric element, media, such as powder layer, organ model, and testing cell, a car body, and construction materials. The “material on which liquid can adhere” includes any material on which liquid can adhere, unless particularly limited.

Examples of the “material to which liquid can adhere” include any materials on which liquid can adhere even temporarily, such as paper, thread, fiber, fabric, leather, metal, plastic, glass, wood, and ceramic.

The “liquid discharge apparatus” may be an apparatus to relatively move a liquid discharge head and a material on which liquid can be adhered. However, the apparatus for discharging liquid is not limited to such an apparatus. The “liquid discharge apparatus” may be, for example, a serial-type apparatus to move the liquid discharge head relative to a sheet material or a line-type apparatus that does not move a liquid discharge head relative to a sheet material.

Examples of the “liquid discharge apparatus” further include a treatment liquid coating apparatus to discharge a treatment liquid to a sheet to coat the treatment liquid on the surface of the sheet to reform the sheet surface and an injection granulation apparatus in which a composition liquid including raw materials dispersed in a solution is injected through nozzles to granulate fine particles of the raw materials.

The terms “image formation”, “recording”, “printing”, “image printing”, and “molding” used herein may be used synonymously with each other.

Numerous additional modifications and variations are possible in light of the above teachings. It is therefore to be understood that, within the scope of the above teachings, the present disclosure may be practiced otherwise than as specifically described herein. With some embodiments having thus been described, it will be obvious that the same may be varied in many ways. Such variations are not to be regarded as a departure from the scope of the present disclosure and appended claims, and all such modifications are intended to be included within the scope of the present disclosure and appended claims.

1. A cooling device comprising:
a metal member configured to thermally couple with an element that generates heat;
a cooling member including a channel for refrigerant to flow; and
a sheet-shaped thermal conductive member between the metal member and the cooling member,
the thermal conductive member including:
an adhesive surface adhered to the metal member; and
a non-adhesive surface pressed against and thermally coupled in contact with the cooling member, the thermal conductive member and the cooling member being separable.

2. The cooling device according to claim 1,
wherein the thermal conductive member and the metal member are substantially a same size.

3. The cooling device according to claim 1,
wherein the metal member is concave.

4. The cooling device according to claim 1, further comprising a fastening member,
wherein the metal member has a first face and a second face that is lower than the first face,
wherein the first face and the cooling member are fastened with the fastening member, and the metal member is pressed against the second face.

5. A liquid discharge apparatus comprising the cooling device according to claim 1.

6. A cooling device comprising:
a metal member configured to thermally couple with an element that generates heat;
a cooling member including a channel for refrigerant to flow; and
a sheet-shaped thermal conductive member between the metal member and the cooling member,
the thermal conductive member including:
an adhesive surface adhered to the cooling member; and
a non-adhesive surface pressed against and thermally coupled with the metal member, the thermal conductive member and the metal member being separable.

7. The cooling device according to claim 6,
wherein the thermal conductive member and the metal member are substantially a same size.

8. The cooling device according to claim 6,
wherein the metal member is concave.

9. The cooling device according to claim 6, further comprising a fastening member,
wherein the metal member has a first face and a second face that is lower than the first face,
wherein the first face and the cooling member are fastened with the fastening member, and the metal member is pressed against the second face.

10. A liquid discharge apparatus comprising the cooling device according to claim 6.

11. A cooling device comprising:
a metal member configured to contact an element that generates heat;
a cooling member including a channel for refrigerant to flow; and
a sheet-shaped thermal conductive member between the metal member and the cooling member,
wherein the channel of the cooling member includes channel portions that are spaced apart and intersect a longitudinal direction of the metal member.

12. The cooling device according to claim 11,
wherein the cooling member and the metal member are fixed via the thermal conductive member at a position not overlapping with the channel of the cooling member.

13. The cooling device according to claim 11,
wherein the position at which the metal member is fixed to the cooling member is selectable.

14. The cooling device according to claim 11,
wherein the thermal conductive member and the metal member are substantially a same size.

15. The cooling device according to claim 11,
wherein the metal member is concave.

16. The cooling device according to claim 11, further comprising a fastening member,
wherein the metal member has a first face and a second face that is lower than the first face,
wherein the first face and the cooling member are fastened with the fastening member, and the metal member is pressed against the second face.

17. A liquid discharge apparatus comprising the cooling device according to claim 11.
